(19) United States
(12) Patent Application Publication
(10) Pub. No.: US 2024/0352582 A1
(43) Pub. Date: Oct. 24, 2024

(54) AN ATOMIC LAYER DEPOSITION APPARATUS AND METHOD

(71) Applicant: BENEQ OY, Espoo (FI)

(72) Inventors: Markus BOSUND, Espoo (FI); Pasi MERILÄINEN, Espoo (FI); Pekka SOININEN, Espoo (FI); Matti MALILA, Espoo (FI)

(21) Appl. No.: 18/681,912

(22) PCT Filed: Aug. 12, 2022
(86) PCT No.: PCT/FI2022/050523

§ 371 Date: Feb. 7, 2024

(30) Foreign Application Priority Data
Aug. 13, 2021 (FI) 20215854

(51) Int. Cl. C23C 16/455

(52) U.S. Cl. CPC C23C 16/45544

(57) ABSTRACT

An atomic layer deposition apparatus arranged to process multiple substrates concurrently in a batch process and a method for loading a substrate batch. The apparatus includes a loading chamber connected to the vacuum chamber through a loading connection; a loading arrangement arranged to move a substrate batch (B) between the loading chamber and the reaction chamber inside the vacuum chamber through the loading connection; and the reaction chamber including a support part forming a reactor bottom; and a cover part forming reactor side walls and a reactor roof. The cover part is movably arranged with respect to the support part between an open position of the reaction chamber and a closed position of the reaction chamber.

### FIELD OF THE INVENTION

The present invention relates to an atomic layer deposition apparatus and more particularly to an atomic layer deposition apparatus as defined in the preamble of the independent claim 1.

The present invention further relates to a method for loading a substrate batch into a reaction chamber of an atomic layer deposition apparatus, and more particularly to a method as defined in the preamble of the independent claim 12.

### BACKGROUND OF THE INVENTION

Publication CN 112323045A discloses a reaction chamber having the top of the reaction chamber open. The substrate batch is loaded from the top of the reaction chamber inside the reaction chamber. The vacuum is broken when the substrate batch is loaded as the loading of the batch is provided from outside of the vacuum chamber.

Loading multiple substrates in a reaction chamber of an atomic layer deposition apparatus, i.e., an ALD reactor, is challenging and requires complicated loading mechanisms which are substrate specific. Substrate loading mechanisms lead compromises with process flow geometry which may cause reduced deposition speed or film uniformity challenges.

### BRIEF DESCRIPTION OF THE INVENTION

An object of the present invention is to provide a simple and effective way of loading a substrate batch into a reaction chamber of an atomic layer deposition apparatus, in which the size of the substrates is not limited to any particular size.

The objects of the invention are achieved by an atomic layer deposition apparatus and a method for loading a substrate batch which are characterized by what is stated in the independent claims. The preferred embodiments of the invention are disclosed in the dependent claims.

The invention is based on the idea of providing a loading chamber in connection with a vacuum chamber having a reaction chamber inside the vacuum chamber and which the reaction chamber has a cover part and a support part which are movably arranged with respect to each other such that the batch can be loaded from the loading chamber horizontally to the reaction chamber and then closing the reaction chamber around the batch.

An atomic layer deposition apparatus according to the invention, which is arranged to process multiple substrates concurrently in a batch process, has a reaction chamber arranged inside a vacuum chamber and comprises a loading chamber connected to the vacuum chamber through a loading connection, and a loading arrangement arranged to move a substrate batch between the loading chamber and the reaction chamber inside the vacuum chamber through the loading connection. The reaction chamber comprising a support part forming a support for the substrate batch and a cover part forming a housing surrounding the substrate batch arranged on the support part. The support part and the cover part together form the reaction chamber such that the cover part is movably arranged with respect to the bottom part between an open position of the reaction chamber and a closed position of the reaction chamber, whereby in the open position of the reaction chamber the support part and the cover part are spaced apart from each other and in the closed position of the reaction chamber the support part and the cover part are connected together for forming a closed reaction chamber.

The loading chamber and the reaction chamber inside the vacuum chamber are preferably arranged such that the loading arrangement is arranged to move the batch from the loading chamber to the reaction chamber such that the batch moves horizontally, therefore the loading connection between the loading chamber and the vacuum chamber is arranged at side walls of the chambers. The reaction chamber is arranged to provide the open position such that the support part to which the batch is transferred is in the same plane with the loading arrangement, whereby the transfer of the batch from the loading chamber to the reaction chamber is arranged horizontally.

The substrate batch means an arrangement in which multiple substrates can be processed at the same time inside the reaction chamber. The substrate batch means in context of this application a rack or similar structure in which several substrates can be placed for simultaneous processing. However, the substrate batch may contain only one substrate when the substrate batch does not include other substrates, which means that there are empty spaces in the rack or similar structure when only one substrate is arranged therein. The substrate batch is arranged to support plurality of substrates stacked one onto another at specified intervals.

The loading connection between the loading chamber and the vacuum chamber preferably comprises a closing mechanism, such as a port valve or like, which is arranged to open and close the loading connection between the loading chamber and the vacuum chamber.

The loading arrangement arranged to move a substrate batch comprises a batch support for supporting the batch and a moving mechanism for moving the batch support between the loading chamber and the reaction chamber.

The reaction chamber comprises a support part on which the batch is placed for processing the substrates and a cover part forming the rest of the housing of the reaction chamber which the cover part is arranged to be connected to the support part and arranged to surround the batch inside the reaction chamber. The reaction chamber is in other words formed as a housing surrounding the substrate batch which the housing is formed of the cover part and the support part. The cover part is movably arranged with respect to the support part between the open position and the closed position such that the cover part is arranged to move toward the support part for closing the reaction chamber.

According to the invention the cover part is arranged to move in a first direction and the loading arrangement is arranged to move the substrate batch in a second direction, which the second direction is transverse to the first direction. In other words, the movement of the loading arrangement is in a different direction from the movement of the cover part, for example, so that the movement of the loading arrangement is horizontal, and the movement of the cover part is vertical, or vice versa.

According to the invention the atomic layer deposition apparatus further comprises a lifter connected to the reaction chamber and arranged to move the cover part between the open position and the closed position of the reaction chamber.

According to the invention the lifter is connected to the cover part of the reaction chamber and arranged to move the cover part in vertical direction relative to the support part of the reaction chamber, which the support part is arranged as stationary inside the vacuum chamber.

According to the invention the lifter is connected to the cover part of the reaction chamber and arranged to move the cover part in horizontal direction relative to the support part of the reaction chamber, which the support part is arranged as stationary inside the vacuum chamber.

The lifter extends from outside the vacuum chamber through the vacuum chamber to the reaction chamber. However, according to the invention the lifter comprises a lifter motor arranged outside the vacuum chamber.

According to the invention the atomic layer deposition apparatus further comprises a thermal reflector arranged inside the vacuum chamber to surround at least part of the cover part of the reaction chamber and to move together with the cover part.

According to the invention the atomic layer deposition apparatus further comprises a thermal reflector movably arranged inside the vacuum chamber such that, when the reaction chamber is in the closed position, the thermal reflector is arranged in a space between the loading connection and the reaction chamber, and when the reaction chamber is in the open position, the thermal reflector is moved away from the loading connection for providing an open path between the loading connection and the open reaction chamber.

The thermal reflector has a reflector surface which is arranged towards the loading connection opening such that the surface of the thermal reflector extends transversely or perpendicularly to the loading connection opening.

According to an embodiment of the invention the thermal reflector is connected to the cover part of the reaction chamber such that the thermal reflector is movable together with the cover part.

According to the invention the thermal reflector is connected to the lifter such that the thermal reflector is movable together with the lifter.

According to the invention the atomic layer deposition apparatus further comprises a vacuum system arranged to provide vacuum conditions to the loading chamber and to the vacuum chamber. The vacuum system may comprise one or more vacuum pumps or vacuum arrangements so as to provide vacuum conditions in the loading chamber and the vacuum chamber as separate operations.

A method for loading a substrate batch into a reaction chamber of an atomic layer deposition apparatus according to the invention for processing the substrates according to the principles of atomic layer deposition method comprises the steps of arranging a substrate batch into a loading chamber; opening a loading connection between the loading chamber and a vacuum chamber; moving the batch from the loading chamber to the reaction chamber inside the vacuum chamber, the reaction chamber being in an open position having a support part of the reaction chamber spaced apart from a cover part of the reaction chamber; and moving the reaction chamber from the open position to a closed position by providing a movement of the cover part with respect to the support part.

The moving of the substrate batch between the loading chamber and the vacuum chamber is preferably arranged horizontally while moving the reaction chamber from the open position to a closed position and from the closed position to the open position is preferably arranged vertically.

According to the invention the method further comprises the step of providing vacuum conditions to the loading chamber and to the vacuum chamber through a vacuum system connected to the loading chamber and to the vacuum chamber prior opening the loading connection between the loading chamber and the vacuum chamber. The vacuum system may comprise multiple vacuum pumps or multiple vacuum arrangements which are separately connected to the loading chamber and to the vacuum chamber to provide vacuum conditions as separate operations or the vacuum system may comprise common vacuum pumps or common vacuum arrangement for the loading chamber and the vacuum chamber.

According to an embodiment of the invention the step of moving the reaction chamber from the open position to the closed position further comprises moving the cover part in vertical direction with a lifter connected to the cover part; and connecting the cover part to the support part for closing the reaction chamber.

According to another embodiment of the invention the step of moving the reaction chamber from the open position to the closed position further comprises moving the support part in vertical direction with a lifter connected to the support part; and connecting the support part to the cover part for closing the reaction chamber.

According to the invention the method is carried out by an atomic layer deposition apparatus according to what is stated above.

An advantage of the invention is that the vacuum is not broken when the substrates are loaded into the reaction chamber because the loading chamber and the vacuum chamber are both provided in the vacuum conditions. Another advantage of the invention is that the loading of substrate is simple by moving the batch horizontally from the loading chamber to the reaction chamber.

### BRIEF DESCRIPTION OF THE DRAWINGS

The invention is described in detail by means of specific embodiments with reference to the enclosed drawings, in which

FIG. 1 shows an atomic layer deposition apparatus according to the invention;

FIG. 2 shows an atomic layer deposition apparatus shown in FIG. 1 in one method step;

FIG. 3 shows an atomic layer deposition apparatus shown in FIG. 1 in another method step;

FIG. 4 shows an atomic layer deposition apparatus shown in FIG. 1 in still another method step;

FIG. 5 an atomic layer deposition apparatus according to the invention; and

FIG. 6 shows an atomic layer deposition apparatus according to the invention.

### DETAILED DESCRIPTION OF THE INVENTION

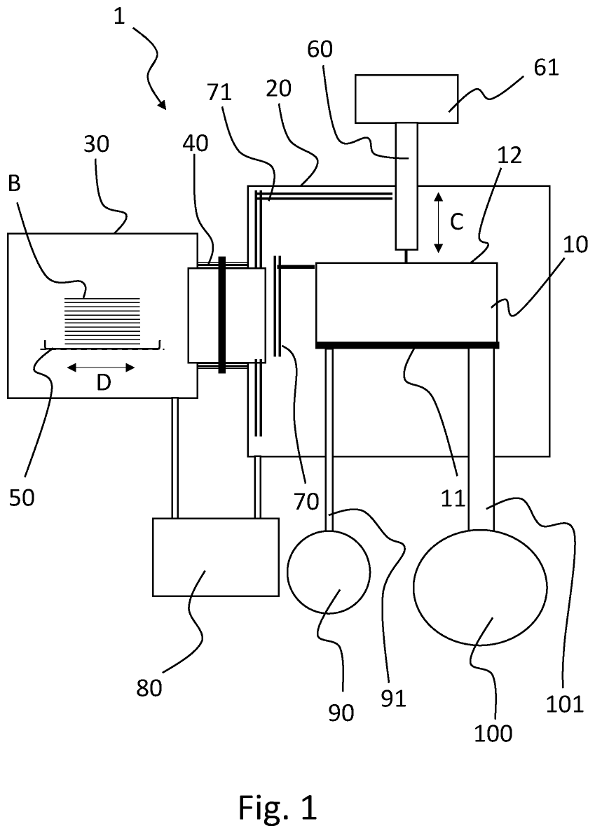

FIG. 1 shows an atomic layer deposition apparatus 1 having a reaction chamber 10 arranged inside a vacuum chamber 20. The reaction chamber 10 is arranged to process substrates according to the principles of atomic layer deposition method in a batch process in which a substrate rack is provided inside the reaction chamber 10 for simultaneously processing the substrates arranged in connection with the substrate rack. The atomic layer deposition apparatus 1 further comprises a loading chamber 30 connected to the vacuum chamber 20 through a loading connection 40. The loading connection 40 is arranged to provide a loading path for a substrate batch B loaded in the loading chamber 30 to be moved from the loading chamber 30 to the reaction chamber 10 inside the vacuum chamber 20 and back from the reaction chamber 10 to the loading chamber 30. A loading arrangement 50 is arranged to move a substrate batch B between the loading chamber 30 and the reaction chamber 10 inside the vacuum chamber 20 through the loading connection 40 along the loading path. The loading arrangement 50 comprises a support for supporting the substrate batch B and a moving mechanism for moving the support. The atomic layer deposition apparatus comprises a reaction chamber 10 comprising a support part forming a support for the substrate batch and a cover part forming a housing surrounding the substrate batch placed on the support part. The support part forming and in this embodiment of the invention also the bottom of the reaction chamber 10 and the cover part 12 forming the reactor side walls and a reactor roof. The support part 11 and the cover part 12 together form the reaction chamber 10 such that the cover part 12 is movably arranged with respect to the bottom part 11 between an open position of the reaction chamber 10 and a closed position of the reaction chamber 10, whereby in the open position of the reaction chamber 10 the support part 11 and the cover part 12 are spaced apart from each other and in the closed position of the reaction chamber 10 the support part 11 and the cover part 12 are connected together for forming a closed reaction chamber. The FIG. 1 shows the reaction chamber 10 in the closed position such that the cover part 12 and the support part 11 are connected together for forming the closed reaction chamber 10. The loading connection 40 connecting the loading chamber 30 and the vacuum chamber 20 having the reaction chamber 10 inside is also in a closed position, separating the loading chamber 30 from the vacuum chamber 20. The substrate batch B is loaded in the loading chamber 30 on the loading arrangement 50. The vacuum system 80 provides vacuum conditions to the loading chamber 30.

The FIG. 1 also shows additional thermal reflectors 71 provided on the inner surfaces of the vacuum chamber 20. However, these additional thermal reflectors 71 are not mandatory but they can be arranged to protect for example surrounding areas of the loading connection 40 or the surrounding areas of the lifter 60.

The FIG. 1 further shows that a gas supply conduit 91 is connected to the support part 11 of the reaction chamber 10 such that the gases are supplied from a gas source 90 through the support part 11 into the reaction chamber 10. A discharge conduit 101 is also connected to the support part 11 of the reaction chamber 10 such that the gases are discharged from the reaction chamber 10 through the support part 11 to a discharge system 100.

The support part 11 is throughout in this application the part on which the substrate batch B is placed for processing the substrates in the reaction chamber 10 and which stays stationary inside the vacuum chamber 20. The arrows C and D present the movement directions of the cover part 12 and of the loading arrangement 50, such that the arrow C represents the reciprocating movement in a first direction and the arrow D represents the reciprocating movement in a second direction which is transverse to the first direction.

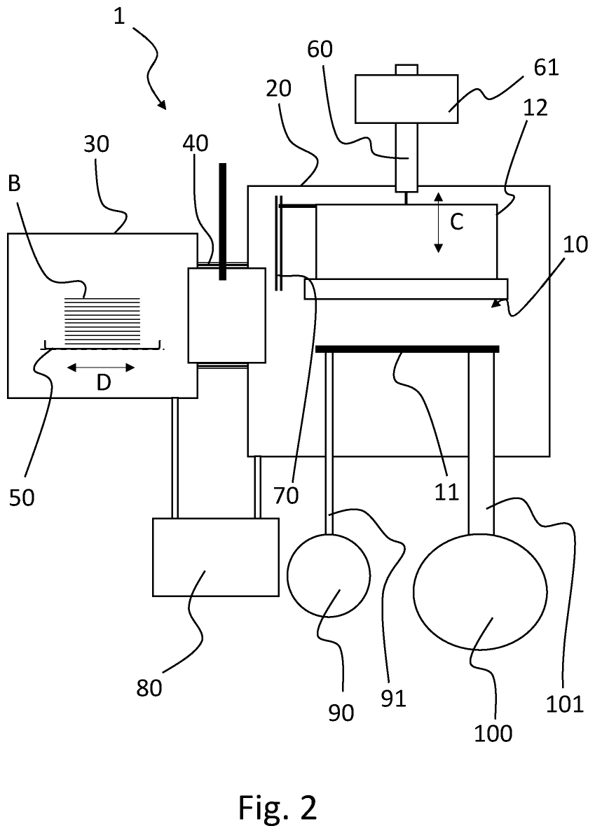

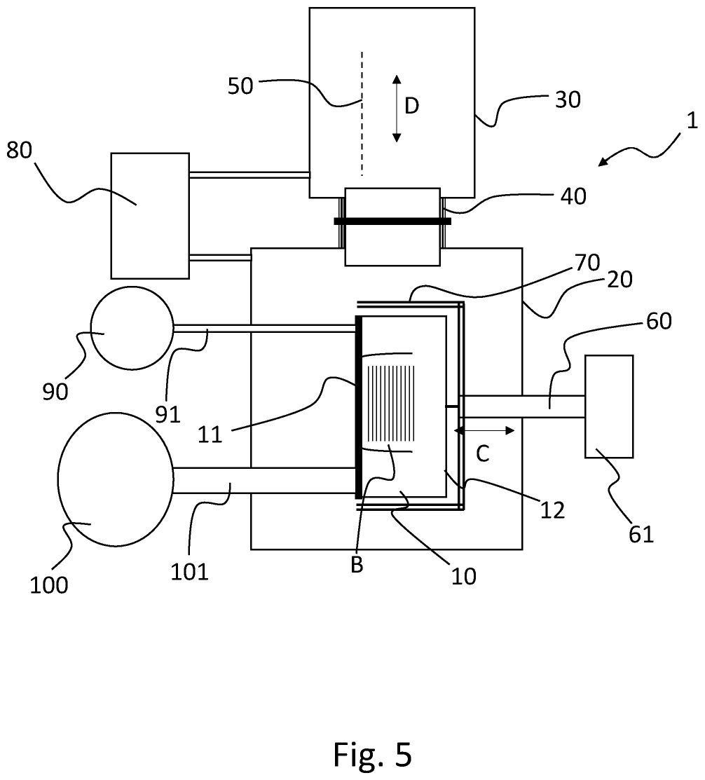

The FIG. 2 shows that the loading connection 40 connecting the loading chamber 30 and the vacuum chamber 20 is open which means that the vacuum system has provided vacuum conditions to the loading chamber 30 and to the vacuum chamber 20 such that the substrate batch B can be moved from the loading chamber 30 to reaction chamber 10 inside the vacuum chamber 20 without breaking the vacuum. The cover part 12 of the reaction chamber 10 has been moved with a lifter 60 having a lifter motor 61 outside the vacuum chamber 20 such that the lifter 60 extends from outside of the vacuum chamber to inside of the vacuum chamber 20 and is connected to the cover part 12 of the reaction chamber 10. In the open position of the reaction chamber 10 the cover part 12 is moved to the upper part of the vacuum chamber 20 with the lifter 60 and the cover part 12 is spaced apart from the support part 11 which remains in its position. The support part 11 is arranged at the same level with the loading arrangement 50 such that the loading path between the loading chamber 30 and the reaction chamber 10 is horizontal. The atomic layer deposition apparatus 1 further comprises a thermal reflector 70 arranged to prevent heat coming from the reaction chamber 10 to reflect to the loading connection 40. In this embodiment of the invention the thermal reflector 70 is arranged in connection with the cover part 12 of the reaction chamber 10 and moved away from the space between the reaction chamber 10 and the loading connection 40 as the cover part 12 is moved to the upper part of the vacuum chamber 20 thereby providing an open loading path for the substrate batch B. FIG. 5 shows another embodiment in connection with the thermal reflectors.

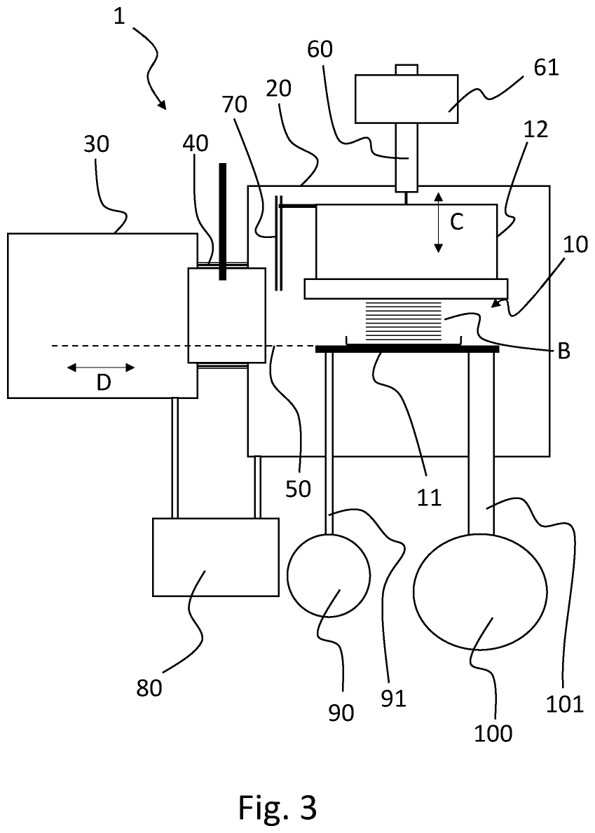

The FIG. 3 shows a state of the atomic layer deposition apparatus 1 in which the substrate batch B is moved from the loading chamber 30 to the reaction chamber 10 inside the vacuum chamber 20 in the second direction D. The reaction chamber 10 is still open and the loading arrangement 50 extends from the loading chamber 30 to the reaction chamber 10. The vacuum conditions are provided in both the loading chamber 30 and the reaction chamber 10 open to the vacuum chamber 20.

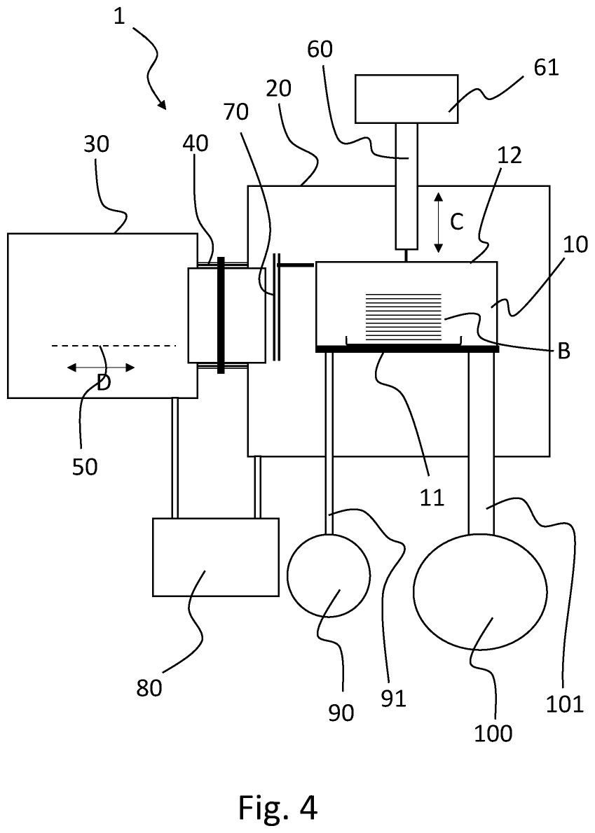

The FIG. 4 shows a state of the atomic layer deposition apparatus 1 in an operation mode in which the cover part 12 of the reaction chamber 10 has been brought into contact with the support part 11 of the reaction chamber 10 by operating the lifter motor 61 for moving the cover part 12 by the lifter 60 so that the cover part 12 is engaged with the support part 11. The cover part 12 has moved in the first direction C. The thermal reflector 70 is also brought in its place in the space between the reaction chamber 10 and the loading connection 40 such that the thermal reflector 70 prevents heat from the reaction chamber 10 to transfer to the loading connection 40. The loading connection 40 is closed and the loading chamber 30 has been separated from the vacuum chamber 20 through the closed loading connection 40. The substrates provided in the substrate batch B are processed in the reaction chamber 10 according to the principles of atomic layer deposition method.

The FIG. 5 shows the atomic layer deposition apparatus 1 according to the invention, in which the loading chamber 30 is arranged above the vacuum chamber 20 such that the loading movement of the substrate batch B is in vertical direction, i.e. the second direction D is in this embodiment vertical. Although the FIG. 5 shows that the loading chamber 30 is above the vacuum chamber 20, the loading chamber 30 can alternatively be provided below the vacuum chamber 20. The movement direction of the cover part 12, i.e. the first direction C is in this embodiment horizontal. The support part 10 comprises a connection arrangement for the substrate batch provided in a rack or other structure for connecting the substrate batch to the support part 11 provided in vertical direction.

FIG. 5 shows also another way to provide the thermal reflector 70 in connection with the reaction chamber 10 for preventing heat to enter the loading chamber 30. The thermal reflector 70 is arranged to cover at least part of the reaction chamber 10 and in this version shown in FIG. 5 the thermal reflector 70 surrounds the cover part 12.

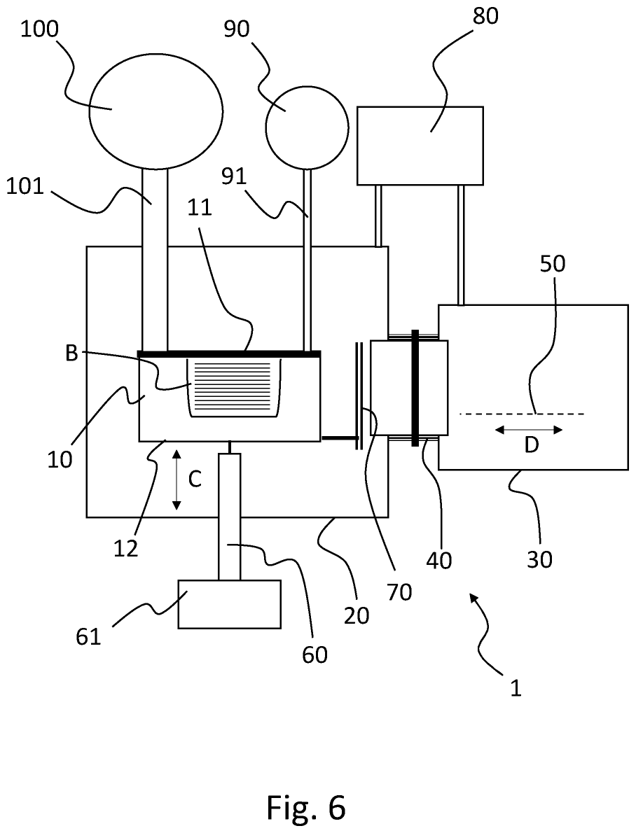

The FIG. 6 shows an alternative way to arrange the reaction chamber 20 inside the vacuum chamber 20. Although the loading chamber 30 is arranged on the opposite site of the vacuum chamber 20 than presented in the FIG. 1, it does not limit this embodiment in any way. The support part 11 is arranged as stationary inside the vacuum chamber 20 so that the cover portion 12 moves from below toward the support part 11 and the substrate batch is suspended therein. The first direction C and the second direction D are however the same as in the FIG. 1. The gas supply and discharge are still provided through the support part 11 to and from the reaction chamber 10 similarly as in connection with all the other embodiments shown in FIGS. 1-5.

The invention has been described above with reference to the examples shown in the figures. However, the invention is in no way restricted to the above examples but may vary within the scope of the claims.

1.-15. (canceled)

16. An atomic layer deposition apparatus arranged to process multiple substrates concurrently in a batch process, the atomic layer deposition apparatus having a reaction chamber arranged inside a vacuum chamber, wherein the atomic layer deposition apparatus further comprises:
a loading chamber connected to the vacuum chamber through a loading connection;
a loading arrangement arranged to move a substrate batch (B) between the loading chamber and the reaction chamber inside the vacuum chamber through the loading connection;
the reaction chamber comprising:
a support part forming a support for the substrate batch (B); and
a cover part forming a housing surrounding the substrate batch (B) arranged on the support part,
which the support part and the cover part together form the reaction chamber such that the cover part is movably arranged with respect to the support part between an open position of the reaction chamber and a closed position of the reaction chamber,
whereby in the open position of the reaction chamber the support part and the cover part are spaced apart from each other and in the closed position of the reaction chamber the support part and the cover part are connected together for forming a closed reaction chamber.

17. The atomic layer deposition apparatus according to claim 16, wherein the cover part is arranged to move in a first direction (C) and the loading arrangement is arranged to move the substrate batch (B) in a second direction (D), which the second direction (D) is transverse to the first direction (C).

18. The atomic layer deposition apparatus according to claim 16, wherein the atomic layer deposition apparatus further comprises a lifter connected to the reaction chamber and arranged to move the cover part between the open position and the closed position of the reaction chamber.

19. The atomic layer deposition apparatus according to claim 18, wherein the lifter is connected to the cover part of the reaction chamber and arranged to move the cover part in vertical direction relative to the support part of the reaction chamber, which the support part is arranged as stationary inside the vacuum chamber.

20. The atomic layer deposition apparatus according to claim 18, wherein the lifter is connected to the cover part of the reaction chamber and arranged to move the cover part in horizontal direction relative to the support part of the reaction chamber, which the support part is arranged as stationary inside the vacuum chamber.

21. The atomic layer deposition apparatus according to claim 18, wherein the lifter comprises a lifter motor arranged outside the vacuum chamber.

22. The atomic layer deposition apparatus according to claim 16, wherein the atomic layer deposition apparatus further comprises a thermal reflector arranged inside the vacuum chamber to surround at least part of the cover part of reaction chamber and to move together with the cover part.

23. The atomic layer deposition apparatus according to claim 16, wherein the atomic layer deposition apparatus further comprises a thermal reflector movably arranged inside the vacuum chamber such that, when the reaction chamber is in the closed position, the thermal reflector is arranged in a space between the loading connection and the reaction chamber, and when the reaction chamber is in the open position, the thermal reflector is moved away from the loading connection for providing an open path between the loading connection and the open reaction chamber.

24. The atomic layer deposition apparatus according to claim 22, wherein the thermal reflector is connected to the cover part of the reaction chamber such that the thermal reflector is movable together with the cover part.

25. The atomic layer deposition apparatus according to claim 22, wherein the thermal reflector is connected to the lifter such that the thermal reflector is movable together with the lifter.

26. The atomic layer deposition apparatus according to claim 16, wherein the atomic layer deposition apparatus further comprises a vacuum system arranged to provide vacuum conditions to the loading chamber and to the vacuum chamber.

27. A method for loading a substrate batch into a reaction chamber of an atomic layer deposition apparatus for processing the substrates according to the principles of atomic layer deposition method, wherein the method comprises the steps of:
arranging a batch (B) of substrates into a loading chamber;
opening a loading connection between the loading chamber and a vacuum chamber;
moving the batch (B) from the loading chamber to the reaction chamber inside the vacuum chamber, the reaction chamber being in an open position having a support part of the reaction chamber spaced apart from a cover part of the reaction chamber; and
moving the reaction chamber from the open position to a closed position by providing a movement of the cover part with respect to the support part.

28. The method for loading a substrate batch into a reaction chamber according to claim 27, wherein the method further comprises the step of:
providing vacuum conditions to the loading chamber and to the vacuum chamber through a vacuum system connected to the loading chamber and to the vacuum chamber prior opening the loading connection between the loading chamber and the vacuum chamber.

29. The method for loading a substrate batch into a reaction chamber according to claim 27, wherein the step of moving the reaction chamber from the open position to the closed position further comprises:
moving the cover part in vertical direction with a lifter connected to the cover part; and
connecting the cover part to the support part for closing the reaction chamber.

30. The method for loading a substrate batch into a reaction chamber of an atomic layer deposition apparatus for processing the substrates according to the principles of atomic layer deposition method, wherein the method comprises the steps of:
arranging a batch (B) of substrates into a loading chamber;
opening a loading connection between the loading chamber and a vacuum chamber;
moving the batch (B) from the loading chamber to the reaction chamber inside the vacuum chamber, the reaction chamber being in an open position having a support part of the reaction chamber spaced apart from a cover part of the reaction chamber; and
moving the reaction chamber from the open position to a closed position by providing a movement of the cover part with respect to the support part, wherein the method is carried out by an atomic layer deposition apparatus according to claim 16.
